(19) United States
(12) Patent Application Publication
(10) Pub. No.: US 2014/0160691 A1
(43) Pub. Date: Jun. 12, 2014

(54) SEMICONDUCTOR MODULE AND METHOD OF MANUFACTURING THE SAME

(71) Applicant: SAMSUNG ELECTRO-MECHANICS CO., LTD., Suwon (KR)

(72) Inventors: Young Ho SOHN, Suwon (KR); Eun Jung JO, Suwon (KR); Jae Hyun LIM, Suwon (KR); Tae Hyun KIM, Suwon (KR)

(73) Assignee: SAMSUNG ELECTRO-MECHANICS CO., LTD., Suwon (KR)

(21) Appl. No.: 14/096,423

(22) Filed: Dec. 4, 2013

(30) Foreign Application Priority Data
Dec. 12, 2012 (KR) 10-2012-0144256

(51) Int. Cl. H01L 25/18; H01L 25/00

(52) U.S. Cl. CPC H01L 25/18; H01L 25/50
USPC 361/736; 29/25.01

(57) ABSTRACT

There is provided a semiconductor module capable of being easily manufactured. The semiconductor module includes: a control part including at least one control device; and a power part including at least one power device, wherein any one of the control part and the power part includes contact pins having elasticity, and the control part and the power part are electrically connected to each other by the contact pins.

### CROSS-REFERENCE TO RELATED APPLICATION

This application claims the benefit of Korean Patent Application No. 10-2012-0144256 filed on Dec. 12, 2012, with the Korean Intellectual Property Office, the disclosure of which is incorporated herein by reference.

### BACKGROUND

The present disclosure relates to a semiconductor module and a method of manufacturing the same, and more particularly, to a power semiconductor module capable of being easily manufactured, and a method of manufacturing the same.

Recently, demand for portable electronic products has rapidly increased. In order to satisfy this demand, it has been necessary to decrease the sizes and weights of electronic components mounted in such portable electronic products.

Therefore, in addition to a method of decreasing sizes of electronic components themselves, a method of installing as many devices and conductive wires as possible in a defined space has been important in designing a semiconductor module.

Meanwhile, at the time of driving a power semiconductor device, a large amount of heat may be generated. Since this heat has an effect on a lifespan and operations of the electronic product, it has been important to radiate the heat of the semiconductor module.

To this end, a power semiconductor module according to the related art has a structure in which both a power device and a control device are mounted on one surface of a circuit board and a heat radiating plate is mounted on the other surface of the circuit board.

However, the power semiconductor module according to the related art as described above may have the following problems.

First, the number of semiconductor devices mounted in the same space is increased due to miniaturization of the power semiconductor module, such that a large amount of heat may be generated in the power semiconductor module. However, the heat radiating plate is only disposed on a lower surface of the power semiconductor module, such that heat may not be efficiently radiated thereby.

In addition, the power semiconductor module according to the related art has a disadvantage in that a size thereof may be increased, since the devices are disposed on a single surface of the circuit board.

Further, devices provided in the power semiconductor module according to the related art or the devices and external connection terminals are generally connected to each other by a wire bonding scheme. Therefore, time required for a manufacturing process is increased due to the wire bonding. In addition, bonding wires may be deformed and damaged due to physical pressure applied to the bonding wires in a process of manufacturing the power semiconductor module and delamination may be generated in a position in which the bonding wires and the devices are bonded to each other due to heat generated at the time of driving the semiconductor module, such that reliability may be decreased at the time of using the power semiconductor module for a long period of time.

Therefore, a power semiconductor module having excellent heat radiation characteristics, being able to be easily manufactured and having reliability secured therein has been demanded.

### RELATED ART DOCUMENT

(Patent Document 1) Korean Patent Laid-Open Publication No. 2007-0065207

### SUMMARY

An aspect of the present disclosure may provide a power semiconductor module having excellent heat radiation characteristics, and a method of manufacturing the same.

Another aspect of the present disclosure may provide a power semiconductor module that does not use a bonding wire, and a method of manufacturing the same.

Another aspect of the present disclosure may provide a power semiconductor module able to be easily manufactured, and a method of manufacturing the same.

According to an aspect of the present disclosure, a semiconductor module may include: a control part including at least one control device; and a power part including at least one power device, wherein any one of the control part and the power part includes contact pins having elasticity, and the control part and the power part are electrically connected to each other by the contact pins.

The control part may include at least one control module substrate having the control device mounted on one surface thereof, and the contact pin may be mounted on the other surface of the control module substrate.

The control part may further include a housing accommodating the control module substrate and the control device therein, and the contact pin may protrude outwardly while penetrating through the housing.

The control part may include two control module substrates, wherein the two control module substrates are coupled to each other so that surfaces thereof on which the control devices are mounted face each other.

The control part may further include at least one spacer interposed between the two control module substrates to maintain an interval between the two control module substrates.

The control part may further include a connecting part disposed on one side of the control module substrate and electrically connected to the exterior.

The power part may include: at least one power module substrate having the power device mounted on one surface thereof; and a frame disposed on one surface of the power module substrate along an edge of the power module substrate to form a thickness of the power part.

The power part may further include at least one contact pad formed on one surface of the power module substrate or an outer surface of the power device and contacting the contact pins.

The semiconductor module may further include: a case accommodating the control part and the power part therein; and at least one heat radiating part fastened to an outer surface of the case.

The case may include: a first accommodating part having the power part coupled thereto while being inserted thereinto in a sliding scheme; and a second accommodating part having the control part accommodated therein.

The first and second accommodating parts may have an opened part formed therebetween, and the power part may be coupled to the first accommodating part so that the power device faces the control part through the opened part.

According to another aspect of the present disclosure, a semiconductor module may include: a control part including a plurality of contact pins protruding on both sides thereof; and two power parts disposed on both sides of the control part, respectively, wherein the power parts are electrically connected to the control part while contacting the contact pins.

According to another aspect of the present disclosure, a method of manufacturing a semiconductor module may include: preparing a control part including a plurality of contact pins protruding on both sides thereof; disposing power parts on both sides of the control part, respectively; and fixedly coupling the power parts and the control part to each other while closely adhering the power parts and the control part to each other so that the power parts contact the contact pins.

The preparing of the control part may include preparing two control module substrates having control devices mounted on one surfaces thereof and the contact pins mounted on the other surface thereof and coupling the two control module substrates to each other so that surfaces thereof on which the contact pins are mounted are directed to the exterior.

The disposing of the power parts may include inserting the power parts into upper and lower cases in a sliding scheme, respectively.

The fixed coupling of the power parts and the control part may include coupling and fixing the upper and lower cases to each other so that the control part is accommodated in a space formed by the upper and lower cases.

The method may further include fastening at least one heat radiating part to outer surfaces of the upper and lower cases.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a perspective view schematically illustrating a semiconductor module according to an exemplary embodiment of the present disclosure;

FIG. 2 is a cross-sectional view of the semiconductor module taken along line A-A′ of FIG. 1;

FIG. 3 is an exploded perspective view of the semiconductor module shown in FIG. 2;

FIG. 4 is a plan view of a power part taken along line B-B′ of FIG. 3;

FIGS. 5 and 6 are plan views of a control part taken along line C-C′ of FIG. 3; and

FIG. 7 is a plan view of the control part taken along line D-D′ of FIG. 3.

### DETAILED DESCRIPTION

Exemplary embodiments of the present disclosure will now be described in detail with reference to the accompanying drawings.

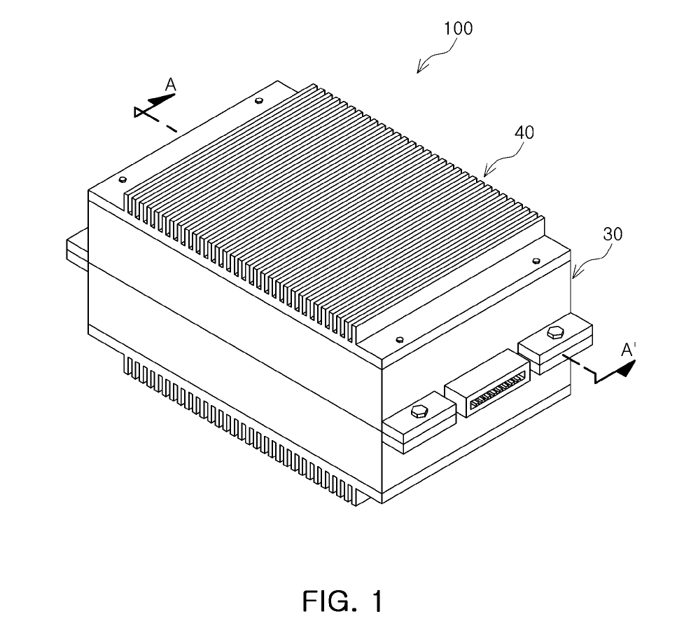

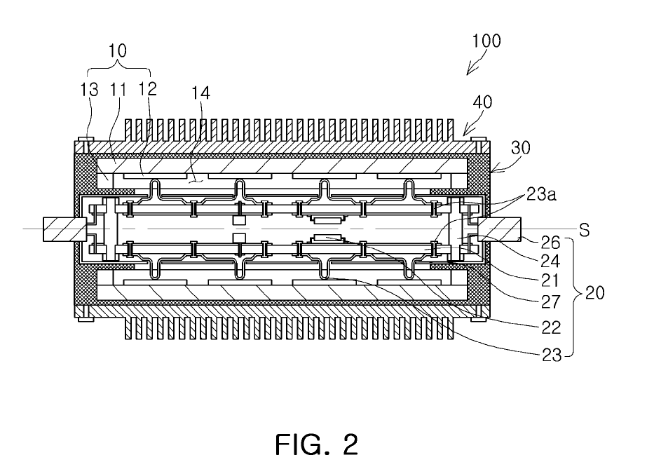

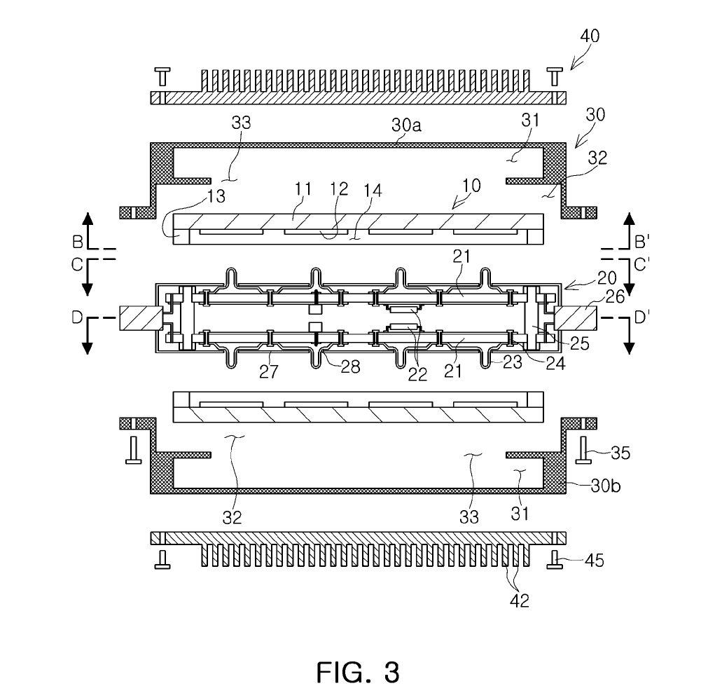

FIG. 1 is a perspective view schematically illustrating a semiconductor module according to an exemplary embodiment of the present disclosure; FIG. 2 is a cross-sectional view of the semiconductor module taken along line A-A′ of FIG. 1; and FIG. 3 is an exploded perspective view of the semiconductor module shown in FIG. 2.

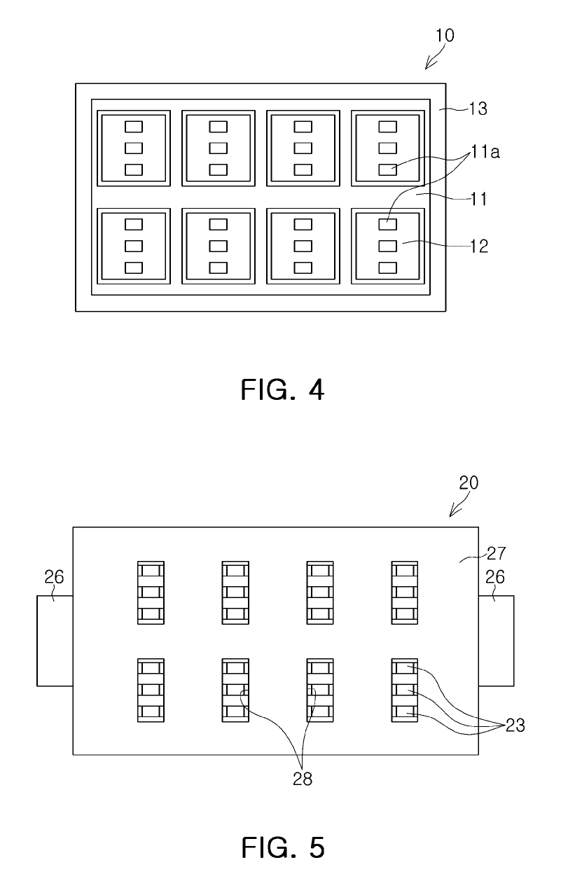

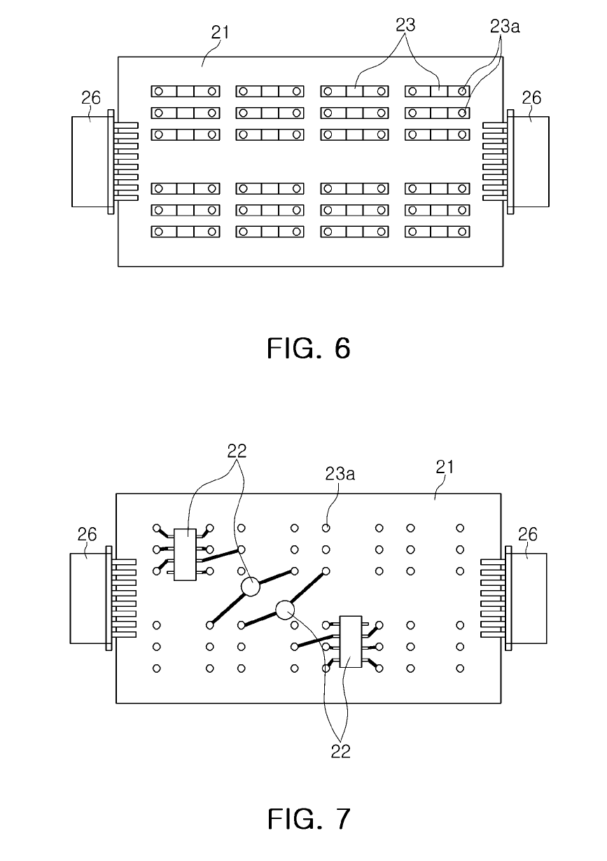

In addition, FIG. 4 is a plan view of a power part taken along line B-B′ of FIG. 3; FIGS. 5 and 6 are plan views of a control part taken along line C-C′ of FIG. 3; and FIG. 7 is a plan view of the control part taken along line D-D′ of FIG. 3. Here, FIGS. 6 and 7 show a control part without a housing.

Referring to FIGS. 1 through 7, the semiconductor module 100 according to the exemplary embodiment of the present disclosure may include a power part 10, a control part 20, a case 30 and a heat radiating part 40.

Meanwhile, the semiconductor module 100 according to the exemplary embodiment of the present disclosure may have a vertically-symmetrical structure based on a central horizontal line (S of FIG. 2). Therefore, in the following description, the same components may be disposed in positions symmetrical to each other based on the central horizontal line. Therefore, a description of overlapped components will be omitted.

The power part 10 may include a power module substrate 11, at least one power device 12, and a frame 13.

The power module substrate 11 may be a printed circuit board (PCB), a ceramic substrate, a pre-molded substrate, a direct bonded copper (DBC) substrate, or an insulated metal substrate (IMS).

In addition, although not shown, wiring patterns, mounting electrodes, and the like, having various forms may be formed on one surface of the power module substrate 11.

The power module substrate 11 may have at least one power device 12 mounted on one surface thereof. The power device 12 may be a power conversion device or a power circuit device for controlling power, such as a servo driver, an inverter, a power regulator, a converter, and the like.

For example, the power device 12 may include a power metal oxide semiconductor field effect transistor (MOSFET), a bipolar junction transistor (BJT), an insulated gate bipolar transistor (IGBT), a diode, or a combination thereof. That is, in the exemplary embodiment of the present disclosure, the power device 12 may include all or some of the above-mentioned devices.

Particularly, the power device 12 according to the exemplary embodiment of the present disclosure may be configured in several pairs, each of which includes the insulated gate bipolar transistor (IGBT) and the diode. However, this is only an example, and the present disclosure is not necessarily limited thereto.

The power devices 12 may be attached to one surface of a power module substrate 11 to be described below through an adhesive member (not shown). Here, the adhesive member may be conductive or non-conductive. For example, the adhesive member may be a conductive solder, a conductive paste, or a tape. In addition, as the adhesive member, a solder, a metal epoxy, a metal paste, a resin based epoxy, an adhesive tape having excellent heat resistance, or the like, may be used.

Meanwhile, at least one contact pad 11a may be formed on one surface of the power module substrate 11 or outer surfaces of the power devices 12 so as to be electrically connected to a control part 20 to be described below. Therefore, the contact pad 11a may be disposed in a position corresponding to a distal end of a contact pin 23 of the control part 20.

In the exemplary embodiment of the present disclosure, the case in which all of the contact pads 11a are disposed on the outer surfaces of the power devices 12 is described by way of example. However, the present disclosure is not limited thereto. That is, the contact pads 11a may be selectively disposed on the power module substrate 11 or the power devices 12 if necessary.

The frame 13 may be coupled to one surface of the power module substrate 11, be formed to have an edge shape, and be disposed along an edge of the power module substrate 11. The frame 13 may be provided in order to secure a thickness of the power part 10. That is, the frame 13 may be provided in order to secure a space 14 in which the power devices 12 of the power part 10 are to be mounted when the power part 10 is coupled to the case 30.

The frame 13 may be formed of various materials such as a metal material, a resin material, or the like, as long as a shape thereof is not easily changed.

The control part 20 may include a control module substrate 21, a control device 22, a contact pin 23, and a housing 27.

The control module substrate 21, a substrate having the control device 22 and the contact pin 23 mounted thereon, may be a printed circuit board (PCB), a ceramic substrate, a pre-molded substrate, a direct bonded copper (DBC) substrate, or an insulated metal substrate (IMS), similar to the power module substrate 11.

The control device 22 may be mounted on one surface, that is, an inner surface, of the control module substrate 21. The control device 22 may be electrically connected to a contact pin 23 to be described below and be electrically connected to the power devices 12 through the contact pin 23. Therefore, the control device 22 may control an operation of the power device 12.

The control device 22 may be, for example, a microprocessor. In addition, the control device 22 may be a passive device such as a resistor, an inverter, or a condenser, or an active device such as a transistor.

Meanwhile, one control device 22 or a plurality of control devices 22 may be disposed with respect to one power device 12. That is, the kind and the number of control devices 22 may be appropriately selected depending on the kind and the number of power devices 12.

In addition, the control devices 22 may be mounted on the control module substrate 21 through an adhesive member (not shown) such as a conductive solder, similar to the power devices 12 described above.

The contact pin 23 may be mounted on the other surface, that is, an outer surface, of the control module substrate 21. The contact pin 23 may be disposed in a form in which it protrudes outwardly from the control module substrate 21 and have a distal end contacting the contact pad 11a of the power module substrate 11.

Particularly, the contact pin 23 according to the exemplary embodiment of the present disclosure may be formed to have a leaf spring shape to have elasticity in a direction in which it protrudes. Therefore, in the case in which the contact pin 23 contacts the contact pad 11a, the contact pin 23 may elastically contact the contact pad 11a.

The contact pin 23 may be fixedly fastened to the control module substrate 21 by a separate fixing pin 23a. The fixing pin 23a may be provided to maintain coupling force between the contact pin 23 and the control module substrate 21 even in the case in which the contact pin 23 is pressed. Therefore, when the coupling force between the contact pin 23 and the control module substrate 21 is secured, the fixing pin 23a may be omitted.

In addition, in the control part 20 according to the exemplary embodiment of the present disclosure, two control module substrates 21 may be coupled to each other in a form in which they face each other. Here, the control module substrates 21 may be coupled to each other so that surfaces thereof on which the control devices 22 are mounted face each other. Therefore, when the control module substrates 21 are coupled to each other, both outer surfaces of the control module substrates 21 may have a shape in which the contact pins 23 protrude thereon.

Here, the two control module substrates 21 may have a spacer 24 interposed therebetween. The spacer 24 may serve to allow the two control module substrates 21 to be spaced apart from each other by a predetermined interval. Therefore, even in the case in which the control module substrates 21 are coupled to each other, a contact between the control devices 22 disposed on surfaces facing each other may be prevented.

A connecting part 26 may be provided in order to electrically connect the semiconductor module 100 to the exterior. To this end, the connecting part 26 may be fastened to at least one of the control module substrates 21 to thereby be electrically connected to the control module substrate 21.

In the exemplary embodiment of the present disclosure, the case in which one connecting part 26 is formed at each of both ends of the control part 20, that is, the case in which a total of two connecting parts 26 are formed is described by way of example. Here, both of the two control modules 21 may be configured to be electrically connected to one connecting part 26. Therefore, in this case, even though only any one of the two connecting parts 26 is used, it may be electrically connected to the two control module substrates 21.

However, the present disclosure is not necessarily limited to the above-mentioned configuration, but may be variously applied. For example, one control module substrate 21 may also be configured to be electrically connected only to any one connecting part 26.

In addition, a configuration in which only one connecting part 26 rather than two connecting parts 26 is disposed and both of the two control module substrates 21 are electrically connected to each other through one connecting part 26 may also be possible.

The housing 27 may form an outer casing of the control part 20 and protect the control part 20 from the exterior. Therefore, the above-mentioned two control module substrates 21 may be coupled to and accommodated in an internal space in which the housing 27 is formed.

In addition, the housing 27 may have at least one penetration hole 28 formed therein. The penetration hole 28 may be used as a path through which the above-mentioned contact pin 23 protrudes outwardly. Therefore, the penetration hole 28 may be formed as an opening having a size larger than that of the contact pin 23.

Referring to the accompanying drawings, the case in which three contact pins 23 are disposed to penetrate through one penetration hole 28 is described in the exemplary embodiment of the present disclosure. However, the present disclosure is not limited to the above-mentioned configuration, but may be variously applied. That is, only one contact pin 23 may be disposed in one penetration hole 28 or one penetration hole 28 may be formed at a larger size, such that three or more contact pins 23 may be disposed to penetrate a single penetration hole 28.

The case 30 may form an outer casing of the entire semiconductor module 100 and protect the power part 10 and the control part 20 from the exterior environment. To this end, the case 30 may include an upper case 30a and a lower case 30b.

The upper case 30a and the lower case 30b may have the same shapes and be symmetrical with each other and be coupled to each other in a manner in which they face each other. In addition, as the upper case 30a and the lower case 30b are coupled to each other, an accommodating space in which the power part 10 and the control part 20 may be accommodated may be formed within the case 30.

The case 30 may fixedly couple the power part 10 and the control part 20 to each other while accommodating the power part 10 and the control part 20 therein. To this end, the case 30 may include a first accommodating part 31 in which the power part 10 is accommodated and a second accommodating part 32 in which the control part 20 is accommodated.

The first accommodating part 31 may have the power part 10 fixedly coupled thereto. The power part 10 according to the exemplary embodiment of the present disclosure may be coupled to the case 30 while being inserted into the first accommodating part 31 in a sliding scheme. Therefore, the first accommodating part 31 may be formed as a space having a size corresponding to an outer casing of the power part 10 so that the power part 10 may be sliding-coupled thereto.

In addition, the first accommodating part 31 may include opened parts 33 formed in the upper case 30a and the lower case 30b, respectively, and having one surface that is partially opened. The opened part 33 may be used as a path through which the power device 12 and the contact pin 23 of the control part 20 are electrically connected to each other. Therefore, the power part 10 may be coupled to the first accommodating part 31 so that the power devices 12 are directed toward the opened part 33, and the contact pins 23 of the control part 20 may be electrically connected to the power module substrate 11 through the opened part 33.

The second accommodating part 32 may be defined as an accommodating space formed in the center in a state in which the upper case 30a and the lower case 30b are coupled to each other. The second accommodating part 32 may have the control part 20 accommodated therein. Therefore, the second accommodating part 32 may be formed as a space corresponding to a shape or a size of the control part 20.

In the case 30 as described above, the upper case 30a and the lower case 30b may be coupled to each other by separate fixing members 45 such as screws, or the like. However, the present disclosure is not limited to the above-mentioned configuration. That is, various schemes such as a fitting coupling scheme, a scheme of using an adhesive member, and the like, may be used if necessary.

In addition, the case 30 may be formed of an insulating material. Particularly, as a material of the case 30, a material such as silicone gel having high thermal conductivity, thermally conductive epoxy, a polyimide, or the like, may be used. However, the present disclosure is not limited thereto.

In the case 30 as described above, the upper case 30a and the lower case 30b may be coupled to each other by separate fixing members 35. However, the present disclosure is not limited to the above-mentioned configuration. That is, the upper case 30a and the lower case 30b may also be adhered to and be formed integrally with each other by an adhesive member interposed therebetween. Here, as the adhesive member, an adhesive, an adhesive tape, or the like, may be used.

The heat radiating part 40 may be fastened to at least one of outer surfaces of the case 30 to radiate heat generated from the power part 10 to the exterior.

The heat radiating part 40 may be formed of a metal material in order to effectively radiate the heat to the exterior. For example, aluminum (Al) or an aluminum alloy capable of being easily used for a comparatively low cost and having excellent thermal conductivity may be used as a material of the heat radiating part 40. However, the present disclosure is not limited thereto. That is, various materials having excellent thermal conductivity, such as graphite, or the like, may be used as a material of the heat radiating part 40 even though they are not a metal.

In addition, the heat radiating part 40 may include a plurality of protrusions 42 or slits formed on an outer surface thereof in order to increase an external area.

The heat radiating part 40 may be fixedly fastened to the case 30 by the separate fixing members 45. However, the present disclosure is not limited to the above-mentioned configuration. That is, the heat radiating part 40 may also be adhered to the case 30 by an adhesive member interposed therebetween. In this case, various materials may be used as a material of the adhesive member as long as they may have high thermal conductivity and are able to bond and firmly fix the heat radiating part 40 and the case 30 to each other.

Next, a method of manufacturing a semiconductor module according to the exemplary embodiment of the present disclosure will be described.

Referring to FIG. 3, in the method of manufacturing a semiconductor module according to the exemplary embodiment of the present disclosure, the control part 20 is first prepared. Here, the control part 20 may be formed by coupling the two control module substrates 21 to each other as described above. That is, the control part 20 may be formed by coupling the two control module substrates 21 to each other through the spacer 24 so that surfaces of the two control module substrates 21 on which the control devices 22 are mounted face each other and covering outer portions of the two control module substrates 21 with the housing 27 to fix the two control module substrates 21 to each other.

Meanwhile, a process of coupling the power part 10 to the case 30 may be performed separately from the above-mentioned process. The power part 10 may be coupled to the case 30 while being inserted into the first accommodating part 31 of the case 30 in a sliding scheme. Here, the power part 10 may be coupled to the case 30 so that a surface of the power part 10 on which the power devices 12 are mounted is exposed to an opened surface of the housing 27.

Since a process of coupling the power part 10 to the case 30 may be performed separately from a process of preparing the control part 20 described above, the process of coupling the power part 10 to the case 30 may be performed before or after the process of preparing the control part 20. Alternatively, the process of coupling the power part 10 to the case 30 may be performed simultaneously with the process of preparing the control part 20. In the case in which the process of coupling the power part 10 to the case 30 is performed simultaneously with the process of preparing the control part 20, a manufacturing time may be decreased.

Next, the case 30 to which the power part 10 is coupled and the control part 20 may be coupled to each other. The control part 20 may be coupled to the case 30 while being accommodated in the second accommodating part 32 formed by the case 30. In this process, the contact pin 23 of the control part 20 may contact the contact pad 11a of the power part 10 through the opened part 33 of the case 30. Therefore, the control part 20 and the power part 10 may be electrically connected to each other.

Meanwhile, in this process, the contact pin 23 may contact the power part 10 while being pressed toward the control module substrate 21 by the power part 10. Therefore, since the contact pin 23 elastically contacts the contact pad 11a of the power part 10, reliability of electrical and physical contact may be secured.

Then, the heat radiating part 40 may be coupled to an outer portion of the case 30. Therefore, the semiconductor module 100 according to the exemplary embodiment of the present disclosure may be completed.

As set forth above, in the semiconductor module according to the exemplary embodiment of the present disclosure, the control parts and the power parts may be disposed in pairs in a form in which they are symmetrical to each other. In addition, the connecting parts for connection with the exterior may be disposed at sides of the semiconductor module. Further, the control part and the power part may be electrically connected to each other while elastically contacting each other by the contact pin having elasticity rather than bonding wires.

Therefore, since the bonding wires that have been used to electrically connect between devices or connect between devices and external terminals according to the related art may be omitted, a plurality of power devices and control devices may be efficiently disposed. Therefore, the semiconductor module may have a size decreased as compared with the related art, such that it may be easily used in various electronic apparatuses that need to be miniaturized and highly integrated.

In addition, since bonding reliability may be secured, as compared with the related art in which bonding wires are used and a problem that the bonding wires are deformed in a process of manufacturing the semiconductor module may be solved, defect generation in the process of manufacturing the semiconductor module may be significantly decreased.

In addition, in the semiconductor module according to the exemplary embodiment of the present disclosure, a double-sided heat radiating structure in which the heat radiating parts are disposed on both surfaces of the case, respectively, may be used, and the power part in which the power devices are mounted and the heat radiating part may be disposed to be significantly adjacent to each other. Therefore, a movement path of the heat may be significantly decreased, and the heat may be radiated through both surfaces of the semiconductor module. Therefore, since significantly improved heat radiation characteristics, as compared with those of the related art may be obtained, long-term reliability of the semiconductor module may be secured.

Further, in the method of manufacturing a semiconductor module according to the exemplary embodiment of the present disclosure, since the contact pin having elasticity is used, the control part and the power part may be electrically connected to each other only by a process of mechanically coupling the control part and the power part to each other. Therefore, since a process of bonding wires, and the like, that has been used according to the related art is omitted, a process of manufacturing the semiconductor module may be very easy and a time required for manufacturing the semiconductor module may be significantly decreased.

The semiconductor module according to the exemplary embodiments of the present disclosure described above is not limited to the above-mentioned exemplary embodiments, but may be variously applied. For example, although the case in which the semiconductor module generally has a rectangular parallelepiped shape has been described by way of example in the above-mentioned exemplary embodiments, the present disclosure is not limited thereto. That is, the semiconductor module may have various shapes such as a cylindrical shape, a polyprismatic shape, and the like, if necessary.

In addition, although the power semiconductor module has been described by way of example in the above-mentioned exemplary embodiments, the present disclosure is not limited thereto, but may be variously applied to an electronic component in which at least one power device is packaged.

While exemplary embodiments have been shown and described above, it will be apparent to those skilled in the art that modifications and variations could be made without departing from the spirit and scope of the present disclosure as defined by the appended claims.

What is claimed is:

1. A semiconductor module comprising:
a control part including at least one control device; and
a power part including at least one power device,
wherein any one of the control part and the power part includes contact pins having elasticity, and the control part and the power part are electrically connected to each other by the contact pins.

2. The semiconductor module of claim 1, wherein the control part includes at least one control module substrate having the control device mounted on one surface thereof, and the contact pin is mounted on the other surface of the control module substrate.

3. The semiconductor module of claim 2, wherein the control part further includes a housing accommodating the control module substrate and the control device therein, and the contact pin protrudes outwardly while penetrating through the housing.

4. The semiconductor module of claim 2, wherein the control part includes two control module substrates, the two control module substrates being coupled to each other so that surfaces thereof on which the control devices are mounted face each other.

5. The semiconductor module of claim 4, wherein the control part further includes at least one spacer interposed between the two control module substrates to maintain an interval between the two control module substrates.

6. The semiconductor module of claim 2, wherein the control part further includes a connecting part disposed on one side of the control module substrate and electrically connected to the exterior.

7. The semiconductor module of claim 2, wherein the power part includes:
at least one power module substrate having the power device mounted on one surface thereof; and
a frame disposed on one surface of the power module substrate along an edge of the power module substrate to form a thickness of the power part.

8. The semiconductor module of claim 7, wherein the power part further includes at least one contact pad formed on one surface of the power module substrate or an outer surface of the power device and contacting the contact pins.

9. The semiconductor module of claim 2, further comprising:
a case accommodating the control part and the power part therein; and
at least one heat radiating part fastened to an outer surface of the case.

10. The semiconductor module of claim 9, wherein the case includes:
a first accommodating part having the power part coupled thereto while being inserted thereinto in a sliding scheme; and
a second accommodating part having the control part accommodated therein.

11. The semiconductor module of claim 10, wherein the first and second accommodating parts have an opened part formed therebetween, and the power part is coupled to the first accommodating part so that the power device faces the control part through the opened part.

12. A semiconductor module comprising:
a control part including a plurality of contact pins protruding on both sides thereof; and
two power parts disposed on both sides of the control part, respectively,
wherein the power parts are electrically connected to the control part while contacting the contact pins.

13. A method of manufacturing a semiconductor module, comprising:
preparing a control part including a plurality of contact pins protruding on both sides thereof;
disposing power parts on both sides of the control part, respectively; and
fixedly coupling the power parts and the control part to each other while closely adhering the power parts and the control part to each other so that the power parts contact the contact pins.

14. The method of claim 13, wherein the preparing of the control part includes preparing two control module substrates having control devices mounted on one surfaces thereof and the contact pins mounted on the other surface thereof and coupling the two control module substrates to each other so that surfaces thereof on which the contact pins are mounted are directed to the exterior.

15. The method of claim 13, wherein the disposing of the power parts includes inserting the power parts into upper and lower cases in a sliding scheme, respectively.

16. The method of claim 15, wherein the fixed coupling of the power parts and the control part includes coupling and fixing the upper and lower cases to each other so that the control part is accommodated in a space formed by the upper and lower cases.

17. The method of claim 16, further comprising fastening at least one heat radiating part to outer surfaces of the upper and lower cases.
